(19) United States
(12) Patent Application Publication
(10) Pub. No.: US 2026/0039288 A1
(43) Pub. Date: Feb. 5, 2026

(54) APPARATUSES AND METHODS FOR SETTING A STANDBY LOGIC STATE OF A DRIVER CIRCUIT

(71) Applicant: MICRON TECHNOLOGY, INC., BOISE, ID (US)

(72) Inventors: Wonjun CHOI, Boise, ID (US); Hyun Yoo LEE, Boise, ID (US)

(73) Assignee: MICRON TECHNOLOGY, INC., BOISE, ID (US)

(21) Appl. No.: 19/272,797

(22) Filed: Jul. 17, 2025

Related U.S. Application Data
(60) Provisional application No. 63/677,553, filed on Jul. 31, 2024.

(51) Int. Cl. H03K 17/16; H03K 3/037

(52) U.S. Cl. CPC H03K 17/16; H03K 3/037

(57) ABSTRACT

An example method that includes determining a leakage characteristic of a driver having a driver output coupled to a signal line; providing a leak detection signal and a keeper control signal to a latch based on the leakage characteristic; setting a latch logic state of the latch based on the keeper control signal; and setting a standby logic state of the driver output based on the latch logic state.

### CROSS REFERENCE TO RELATED APPLICATION

This application claims the benefit of U.S. Provisional Patent Application No. 63/677,553, filed Jul. 31, 2024. This application is incorporated by reference herein in its entirety and for all purposes.

### BACKGROUND

A data path may experience current leakage, which has been an ongoing challenge in data path driver design.

In operation, current leakage may occur in an inactive driver as a p-channel leak and/or an n-channel leak. In an example of a p-channel leak, the p-channel leak may be greater when the data path maintains a low logic state than when the data path maintains a high logic state, and thus causing an increase in overall current leakage. In an example of an n-channel leak, the n-channel leak may be greater when the data path maintains a high logic state than when the data path maintains a low logic state, and thus causing an increase in overall current leakage. In some examples, both p-channel leak and n-channel leak exist. Therefore, it may be desirable to reduce current leakage in inactive data path drivers.

### BRIEF DESCRIPTION OF THE DRAWINGS

FIG. 1 is a block diagram of a semiconductor device according to an embodiment of the present disclosure.

FIG. 2 is a block diagram of a portion of a data path in a semiconductor device according to an embodiment of the present disclosure.

FIG. 3 is a schematic diagram of a repeater circuit according to an embodiment of the present disclosure.

FIG. 4 is a schematic diagram of a keeper circuit according to a first embodiment of the present disclosure.

FIG. 5 is a truth table in accordance with the first embodiment of the present disclosure.

FIG. 6 is a schematic diagram of a keeper circuit according to a second embodiment of the present disclosure.

FIG. 7 is an example timing diagram according to the second embodiment of the present disclosure.

FIG. 8 is a schematic diagram of a leak detection circuit according to an embodiment of the present disclosure.

### DETAILED DESCRIPTION

This disclosure describes examples of identifying a current leakage in an inactive driver and reducing the current leakage in inactive data path drivers.

Various embodiments of the present disclosure will be explained below in detail with reference to the accompanying drawings. The following detailed description refers to the accompanying drawings that show, by way of illustration, specific aspects and embodiments of the disclosure. The detailed description includes sufficient detail to enable those skilled in the art to practice the embodiments of the disclosure. Other embodiments may be utilized, and structural, logical and electrical changes may be made without departing from the scope of the present disclosure. The various embodiments disclosed herein are not necessary mutually exclusive, as some disclosed embodiments can be combined with one or more other disclosed embodiments to form new embodiments.

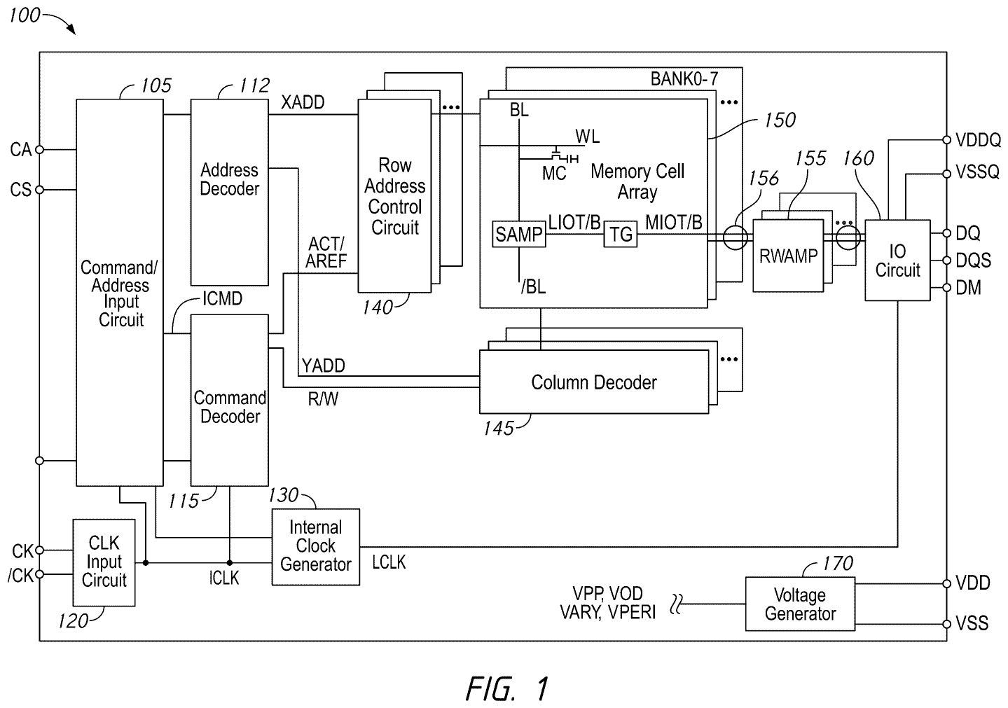

FIG. 1 is a block diagram of a semiconductor device 100 according to an embodiment of the present disclosure. In some embodiments, the semiconductor device 100 may include, without limitation, a DRAM device, such as a double data rate (DDR) memory or a low power DDR (LPDDR) memory integrated into a single semiconductor chip, for example. The semiconductor device 100 includes a memory array 150. The memory array 150 includes a plurality of banks, each bank including a plurality of word lines WL, a plurality of bit lines BL and/BL, and a plurality of memory cells MC arranged at intersections of the plurality of word lines WL and the plurality of bit lines BL. The memory cells MC are volatile memory cells, requiring periodic refreshing in order to maintain the data stored in the memory array.

The selection of the word line WL is performed by a row address control circuit 140 and the selection of the bit line BL is performed by a column decoder 145. Sense amplifiers (SAMP) are located for their corresponding bit lines BL and/BL coupled to at least one respective local I/O line pair (LIOT/B), which is in turn coupled to at least one respective main I/O line pair (MIOT/B), via transfer gates (TG), which function as switches.

The memory array 150 may be divided into memory banks BANK0-7, with each memory bank having a regular array and a redundant array. The regular array includes memory cells that are typically used to store data with the memory cells corresponding to respective memory addresses. The redundant array includes memory cells that may be used to “repair” defective memory cells of the regular array. The memory cells may be configured as redundant rows of memory and redundant columns of memory. The redundant rows of memory may be used to repair rows of memory of the regular array, and the redundant columns of memory may be used to repair columns of memory of the regular array. The redundant memory is used to repair defective memory cells of the regular array by having the memory addresses corresponding to the defect memory cells mapped to memory cells of the redundant array. As a result, when the memory address for the defective memory location is provided to the semiconductor device 100, the memory location in the redundant array to which the memory address is mapped is accessed instead of the defective memory location in the regular array corresponding to that memory address.

The semiconductor device 100 may employ a plurality of external terminals, which include command/address terminals CA that are coupled to a command and address bus to receive commands and addresses. The plurality of external terminals further includes clock terminals CK and CK/to receive clock signals, data terminals DQ and data mask terminals DM, and power supply terminals VDD, VSS, VDDQ, and VSSQ.

The command/address terminals CA may be supplied with memory addresses, for example, from a memory controller. The memory addresses supplied to the command/address terminals CA are transferred, via a command/address input circuit 105, to an address decoder 112. The address decoder 112 receives the memory addresses and supplies decoded row addresses XADD to the row address control circuit 140, and supplies decoded column addresses YADD to the column decoder 145.

The command/address terminals CA may further be supplied with commands from, for example, a memory controller. The commands may be provided as internal command signals ICMD to a command decoder 115 via the command/address input circuit 105. The command decoder 115 includes circuits to decode the internal commands ICMD to generate internal commands and signals for performing operations. For example, the command decoder 115 may provide activation commands ACT and refresh commands AREF to the row address control circuit 140 to select a word line and may provide read/write commands R/W to the column decoder 145 to select a bit line. Refresh commands AREF may be provided by the command decoder 115 to the row control circuit 140 when a refresh operation is to be performed. The refresh command AREF may represent auto refresh commands that result from the semiconductor device 100 receiving a refresh command, and may also represent self-refresh commands, which are generated internally when the semiconductor device 100 is set in a self-refresh mode.

When an activate command and a read command are received and a memory address is timely supplied with the read command, read data is read from a memory cell in the memory array 150 designated by the memory address. The read data is output to outside from the data terminals DQ via read/write amplifiers 155 and the input/output circuit 160.

When an activate command and a write command are received and a memory address is timely supplied with the write command, write data and a data mask (when applicable) are supplied to the data terminals DQ and DM, and the write data is written to a memory cell in the memory array 150 designated by the memory address. The write data is received by data receivers in the input/output circuit 160, and supplied via the input/output circuit 160 and the read/write amplifiers 155 to the memory array 150.

The read/write data may be provided on a data path between the memory array 150 and the input/output circuit 160. In some embodiments, the data path includes signal lines 156 coupled to a plurality of repeater circuits and one or more keeper circuits. An example repeater circuit may include receiver circuits and may include driver circuits that provide read and write data over the signal lines of the data path. In some embodiments of the disclosure, the keeper circuit may set a standby logic state of the signal line 156.

As previously described, the volatile memory cells are periodically refreshed in order to maintain the data stored by the memory array. The memory cells are typically refreshed as rows of memory cells. The row address control circuit 140 may include a refresh control circuit that is used during refresh operations. Refresh operations are performed when active refresh commands AREF are provided to the row address control circuit 140. Each refresh command AREF results in memory locations associated with a refresh address to be refreshed. In some embodiments of the disclosure, the refresh address may be generated internally in the semiconductor device 100. Similar circuits and operation may be included in the column decoder 145 in some embodiments of the disclosure.

Turning to an explanation of the external terminals included in the semiconductor device 100, the clock terminals CK and/CK are supplied with complementary external clock signals. The external clock signals may be supplied to a clock input circuit 120. The clock input circuit 120 may generate internal clock signals ICLK. The internal clock signals ICLK are supplied to internal clock generator circuit 130 and to the command decoder 115. Circuits of the internal clock generator circuit 130 provide various internal clock signals LCLK based on the internal clock signals ICLK. The internal clock signals LCLK may be used for timing the operation of various internal circuits. For example, the LCLK signals may be provided to the input/output circuit 160 for timing the operation of the input/output circuit 160 to provide and receive data on the data terminals DQ.

The power supply terminals VDD and VSS are supplied with power supply potentials. These power supply potentials are supplied to an internal voltage generator circuit 170. The internal voltage generator circuit 170 generates various internal potentials VPP, VOD, VARY, VPERI, and the like based on the power supply potentials provided to the power supply terminals VDD and VSS. The internal potential VPP is mainly used in the row address control circuit 140, the internal potentials VOD and VARY are mainly used in the sense amplifiers SAMP included in the memory array 150, and the internal potential VPERI is used in many other peripheral circuit blocks.

The power supply terminals VDDQ and VSSQ are also supplied with power supply potentials. The power supply potentials are supplied to the input/output circuit 160. The power supply potentials provided to the power supply terminals VDDQ and VSSQ may be the same potentials as the power supply potentials provided to the power supply terminals VDD and VSS in some embodiments of the disclosure. Dedicated power supply potentials are provided to the power supply terminals VDDQ and VSSQ so that power supply noise generated by the input/output circuit 160 does not propagate to the other circuit blocks.

In some examples, the semiconductor device 100 may use various configuration parameters or settings during power-up and operation, such as start-up parameters and settings, redundancy settings, options settings, identification (ID) settings, or any combination thereof. The configuration parameters may be used by the semiconductor device 100 to specify operational characteristics, such as voltage levels, timing configurations, I/O and other bus configurations, etc.

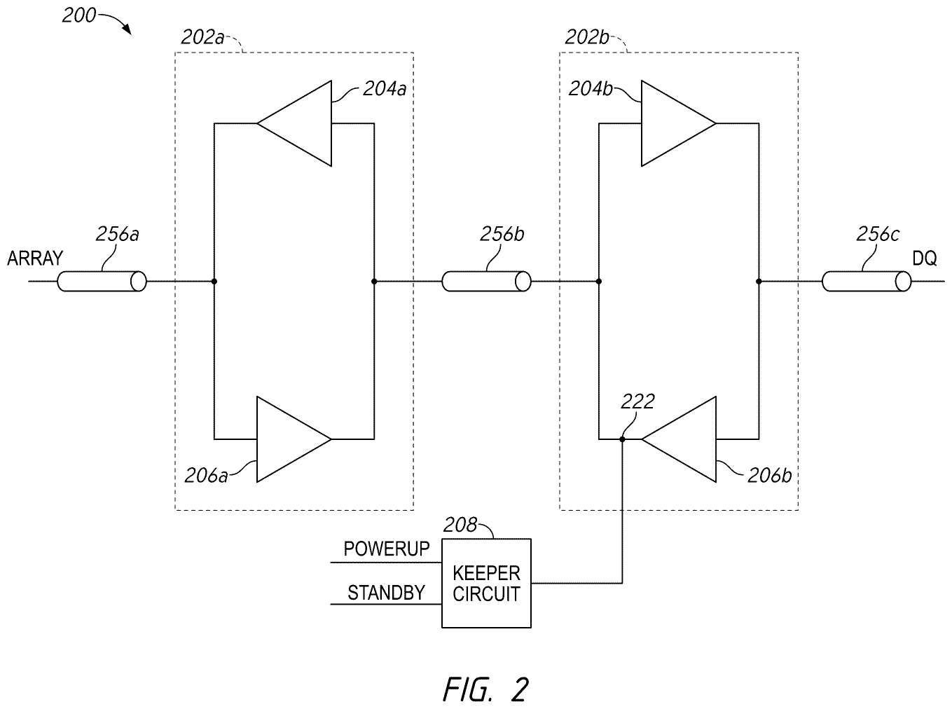

FIG. 2 is a block diagram of a portion of a data path 200 in a semiconductor device according to an embodiment of the present disclosure. The semiconductor device of FIG. 1 may implement the data path 200, in some examples.

The data path 200 includes a signal line 256 coupled to repeater circuits 202a and 202b, and further includes a keeper circuit 208 coupled to at least one of the repeater circuits 202a and 202b. While FIG. 2 shows that the keeper circuit 208 is coupled to the repeater circuit 202b, the keeper circuit 208 is not limited to being coupled to the repeater circuit 202b. In other examples, the keeper circuit 208 may be coupled to the repeater circuit 202a. The signal line 256 includes signal line portions 256a, 256b, and 256b. More or fewer signal line portions, repeater circuits and/or keeper circuits may be included in the data path 200.

In some examples (e.g. a read operation), data may be read from the array and provided to the DQ pad in the direction through the repeater circuits 202a and 202b. In other examples (e.g. a write operation), data may be written from the DQ pad and provided to the array in the direction through the repeater circuits 202b and 202a. In some embodiments, the DQ pad may be included in the data terminals DQ and the array may be included in the memory array 150 of the semiconductor device 100 of FIG. 1.

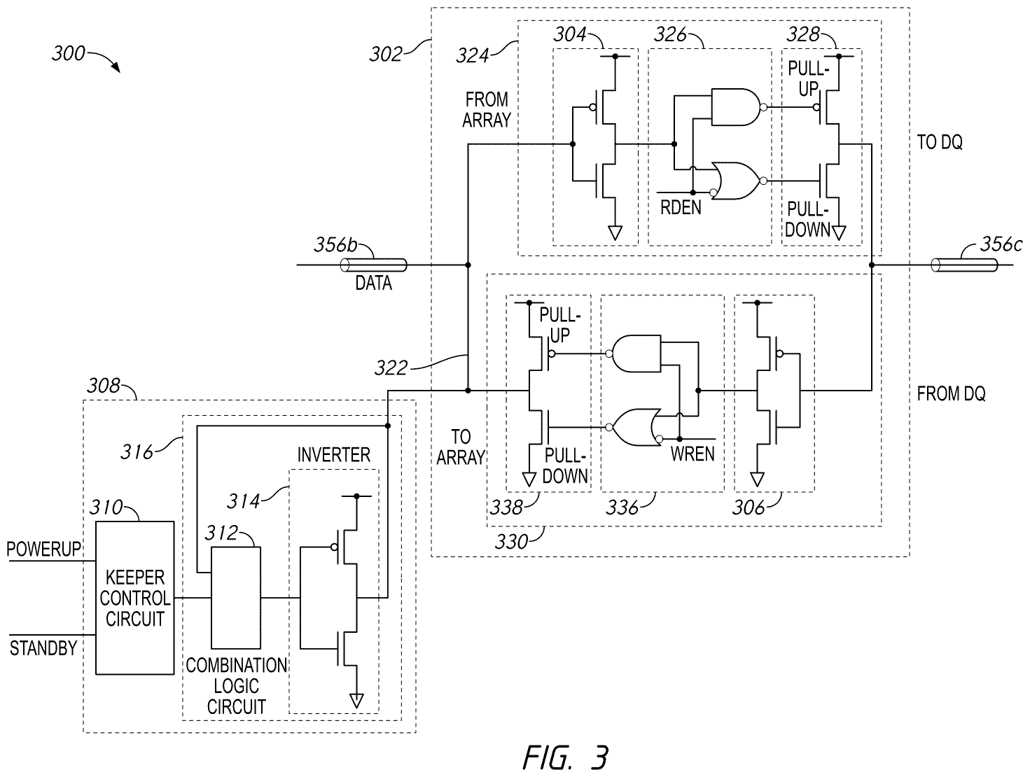

The repeater circuit 202a may include a DQ to array (D-A) driver circuit 204a and an array to DQ (A-D) driver circuit 206a pair coupled to the signal line portions 256a and 256b. The repeater circuit 202b may include a A-D driver circuit 204b and a D-A driver circuit 206b coupled to the signal line portions 256b and 256c. The driver circuits 206a/204b may receive and provide data having a logic state along the signal line 256 between the array and the DQ pad. The driver circuits 206b/204a may drive data along the signal line 256 between the DQ pad and the array. In some embodiments, the driver circuits 204a and 204b are tri-state drivers that can drive a signal line to a high logic state, a low logic state, or a high impedance state. In some embodiments, the driver circuits 206a and 206b are tri-state drivers that can drive a signal line to a high logic state, a low logic state, or a high impedance state. Details about a repeater circuit and driver circuits of the repeater circuit, e.g., the driver circuits 204a/204b and driver circuits 206a/206b, will be described in greater detail below with reference to FIG. 3.

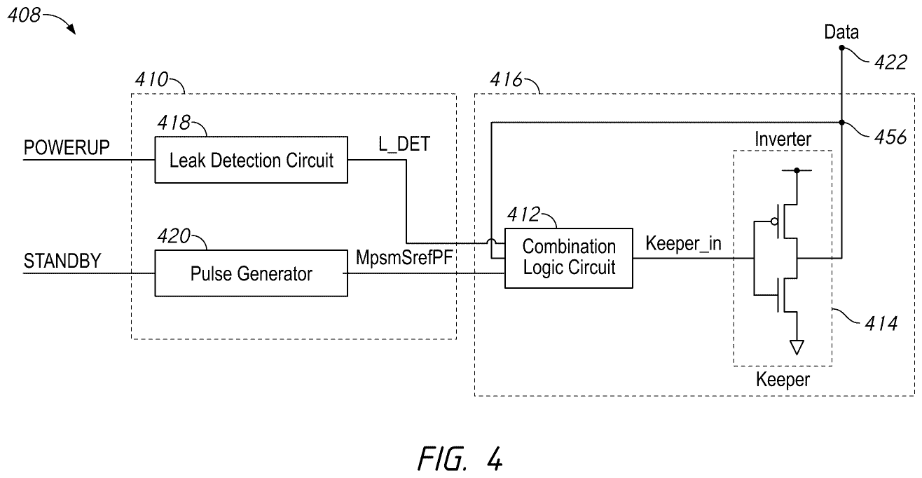

In some examples, the keeper circuit 208 may be coupled to a node 222 at an output of the driver circuit 206b of the repeater circuit 202b. In other examples, the keeper circuit may be coupled to a node (not shown) at an output of the driver circuit 206a of the repeater circuit 202a. In some embodiments, a keeper circuit is coupled to the output of the driver circuits 206a and 206b. The keeper circuit 208 may set a standby logic state of the output of the driver circuit 206b (and in some examples, also the output of the driver circuit 206a and/or the signal line 256) during power-up (e.g., DRAM power-up sequence) and/or standby. During power-up, a control signal POWERUP is active (e.g., active high logic state). During standby, a control signal STANDBY is active (e.g., active high logic state). In some examples, STANDBY control signal may be active during a self-refresh, Max Power Saving Mode (MPSM), and/or Pre-charge standby. The keeper circuit will be described in greater detail below with reference to FIGS. 3 and 4.

In a read operation, data may be read from the memory array and provided to the DQ pad along the data path 200 via the signal line 256, and the driver circuit 206a and driver circuit 204b. In a write operation, data may be provided from the DQ pad to the memory array along the data path 200 via the signal line 256, and the driver circuit 206b and the driver circuit 204a.

FIG. 3 is a schematic diagram of a portion of the data path 300 according to an embodiment of the present disclosure. In some embodiments, the data path 300 may be included in the data path 200 of FIG. 2. In some embodiments, the data path 300 may be included in the semiconductor device 100 of FIG. 1. The data path 300 includes a repeater circuit 302 coupled to signal line 356, for example, coupled to signal line portions 356b and 356c. A keeper circuit 308 is coupled to a repeater circuit 302. The repeater circuit 302 may be included in repeater circuits 202a/202b of FIG. 2 in some embodiments. The keeper circuit 308 may be included in the keeper circuit 208 of FIG. 2 in some embodiments. The signal line 356 may be included in the signal line 256 of FIG. 2 in some embodiments.

The repeater circuit 302 includes an A-D driver circuit 324 and a D-A driver circuit 330. The driver circuits 324 and 330 are coupled to the signal line portions 356b and 356c. In some embodiments, the driver circuits 324 and 330 are tri-state driver circuits that can provide high logic level data or low logic data, or have high impedance at its output.

The driver circuit 324 includes a receiver 304, a driver logic 326 coupled to the receiver 304, and a driver stage 328 coupled to the driver logic 326. The driver circuit 324 may receive data from the signal line portion 356b and provide data to signal line portion 356c. In some embodiments, the receiver 304 includes an inverter circuit including a p-channel pull-up transistor and an n-channel pull-down transistor.

The driver logic 326 includes logic circuits that receive data from the receiver 304 and a read enable signal RDEN and provide driver control signals PULL-UP and PULL-DOWN to a driver stage 328. The RDEN signal is active for a read operation that provides data from the array to the DQ, and may be provided by command decoder in response to a read command. The driver stage 328 comprises a pull-up transistor and a pull-down transistor configured to receive the driver control signals PULL-UP and PULL-DOWN, respectively. The driver stage 328 drives data onto the signal line portion 356c. In some embodiments, the data driven by the driver circuit 324 may be complementary to the logic state of the data provided to the driver circuit 324 by the signal line portion 356b. The data may have a logic state (e.g., “1” or “0”). The output of the driver circuit 324 may be at a high impedance state when the pull-up and pull-down transistors are both deactivated to be non-conductive.

The repeater circuit 302 also includes a driver circuit 330. The driver circuit 330 includes a receiver 306, driver logic 336 coupled to the receiver 306, and a driver stage 338 coupled to the driver logic 336. In some embodiments, the driver circuit 330 can drive its output to a high logic state, a low logic state, or a high impedance state.

The driver circuit 330 may receive data from the signal line portion 356c and provide data to signal line portion 356b. In some embodiments, the receiver 306 includes an inverter circuit including a p-channel pull-up transistor and an n-channel pull-down transistor.

The driver stage 338 may include a p-channel pull-up transistor and an n-channel pull-down transistor. The driver logic 336 may include logic circuits that receive data from the receiver 306 and a write enable signal WREN and provide driver control signals PULL-UP and PULL-DOWN to pull-up transistor and the pull-down transistor, respectively, of the driver stage 338 to drive data onto the signal line portion 356b. The WREN signal is active for a write operation that provides data from the DQ to the array, and may be provided by command decoder in response to a write command. In some embodiments, the data driven by the driver circuit 330 may be complementary to the logic state of the data provided to the driver circuit 330 by the signal line portion 356b. The data may have a logic state (e.g., “1” or “0”). The output of the driver circuit 330 may be at a high impedance state when the pull-up and pull-down transistors are both deactivated to be non-conductive.

In operation, the driver circuit 330 drives the signal line portion 356b to a high logic state when the driver logic 336 provides the PULL-UP signal having a low logic state and the PULL-DOWN signal having a low logic state (pull-up transistor ON and pull-down transistor OFF). The driver circuit 330 drives the signal line portion 356b to a low logic state when the driver logic 336 provides the PULL-UP signal having a high logic state and the PULL-DOWN signal having a high logic state (pull-up transistor OFF and pull-down transistor ON). The driver circuit 330 drives the output to a high-impedance state when the driver logic 336 provides the PULL-UP signal having a high logic state and the PULL-DOWN signal having a low logic state (pull-up transistor OFF and pull-down transistor OFF).

The keeper circuit 308 is coupled to a node 322 at an output of the driver circuit 330. The keeper circuit 308 includes a keeper control circuit 310 and a latch 316. The latch 316 includes a combination logic circuit 312, and an inverter 314. The keeper circuit 308 may set a standby logic state of the output of the driver circuit 330 at the node 322 during power-up (e.g., DRAM power-up sequence) and/or standby to reduce current leakage during the power-up and/or standby.

The keeper control circuit 310 is coupled to the latch 316. In some examples, the keeper control circuit 310 may provide a keeper control signal to the latch 316 based on a logic state of a control signal STANDBY. The STANDBY signal is active when a semiconductor device including the keeper circuit 408 is in standby. The STANDBY signal may be provided by a command decoder (e.g., command decoder 115 of FIG. 1) in some embodiments. In some examples, the STANDBY control signal may be active during a self-refresh, Max Power Saving Mode (MPSM), and/or Pre-charge standby. The keeper control signal provided to the latch 316 may set the logic state of the latch 316, which in turn sets a standby logic state of the output of the driver circuit 330. The signal line may be implemented by the signal line 156 of FIG. 1, and/or the signal line 256 of FIG. 2.

The latch 316 receives the keeper control signal from the keeper control circuit 310. The combination logic circuit 312 may provide a keeper internal signal to the inverter 314 based on the keeper control signal and the logic state of the signal line 356b at the node 322. The keeper internal signal may activate the inverter 314 to set a logic state of the output of the driver circuit 330 at the node 322 to reduce leakage current of pull-up and/or pull-down transistors of driver circuits of the data path. For example, the keeper internal signal may cause the inverter 314 to switch logic states when the logic state of the initial data on the signal line 356b at the node 322 matches the logic state of the keeper internal signal. As a result, the logic state of the standby data on the portion of signal line 356b may be inverted. In another example, the inverter 314 is caused by the keeper internal signal to maintain a logic state, for example, when the state of the standby data on the signal line may be the same as the logic state of the initial data. Additional details about the keeper circuit 308 will be described below with reference to FIG. 4.

FIG. 4 is a schematic diagram of a keeper circuit 408 according to an embodiment of the present disclosure. The keeper circuit 408 includes a keeper control circuit 410 and a latch 416. The keeper circuit 408 may be included in the keeper circuit 208 of FIG. 2 in some embodiments. The keeper circuit 408 may be included in the keeper circuit 308 of FIG. 3. The latch 416 may be included in the latch 316 of FIG. 3.

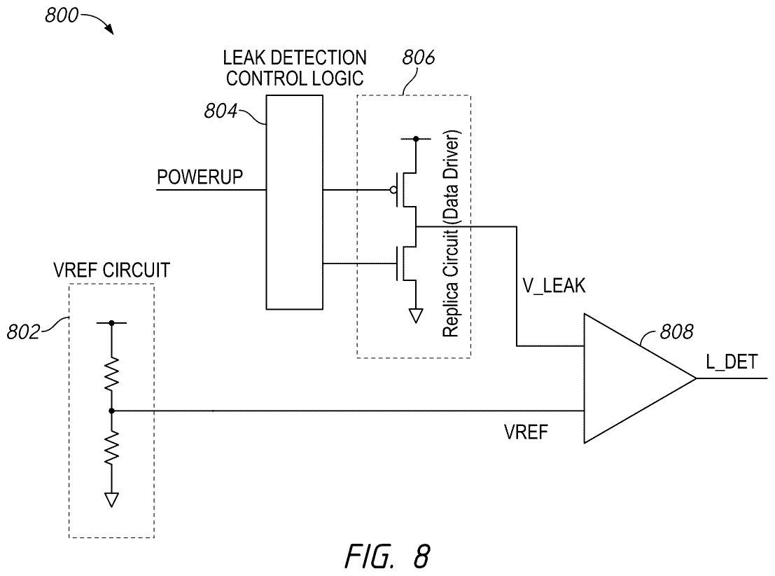

The keeper control circuit 410 includes a leak detection circuit 418 and a pulse generator 420. The keeper control circuit 410 may determine a leakage characteristic of a driver of a data path (e.g., driver circuit 206a/206b of FIG. 2 and/or driver circuit 324/330 of FIG. 3) and provide a leak detection signal L_DET according to the leakage characteristic. The leakage characteristic may be based on a comparison of the p-channel leakage and the n-channel leakage of a replica driver circuit (described with reference to replica circuit 806 of FIG. 8 below). The replica driver circuit may include pull-up and pull-down transistors that have transistor characteristics that model the transistor characteristics of pull-up and pull-down transistors included in the driver circuits of a data path.

For example, the leak detection circuit 418 may determine the leakage characteristic and generate the leak detection signal indicative of whether the pull-up transistor or the pull-down transistor of the replica driver circuit has greater leakage when inactive. For example, if the n-channel pull-down transistor leakage is greater than the p-channel pull-up transistor leakage, the leak detection signal L_DET may be set to low; if the p-channel pull-up transistor leakage is greater than the n-channel pull-down transistor leakage, the leak detection signal L_DET may be set to high.

The pulse generator 420 may generate a keeper control signal MpsmSrefPF based on the logic state of control signal STANDBY. The STANDBY signal is active when a semiconductor device including the keeper circuit 408 is in standby. The STANDBY signal may be provided by a command decoder (e.g., command decoder 115 of FIG. 1) in some embodiments. In some examples, the STANDBY control signal may be active during a self-refresh, Max Power Saving Mode (MPSM), and/or Pre-charge standby. The pulse generator 420 provides a pulse for the MpsmSrefPF control signal when the STANDBY control signal becomes active to set the logic state of the latch 416, which in turn sets a standby logic state of the output of the driver. The signal line 456 may be implemented by the signal line 156 of FIG. 1, the signal line 256 of FIG. 2, and/or the signal line 356 of FIG. 3.

The latch 416 receives the leak detection signal L_DET and the keeper control signal MpsmSrefPF from the keeper control circuit 410. In the example of FIG. 4, the latch 416 includes a combination logic circuit 412 and an inverter 414. The latch 416 is coupled to the output of a driver. In some examples, the latch 416 may have a logic state, which is set by the keeper control signal MpsmSrefPF when the STANDBY signal is active. The logic state of the latch 416 sets the standby logic state of the output of the driver.

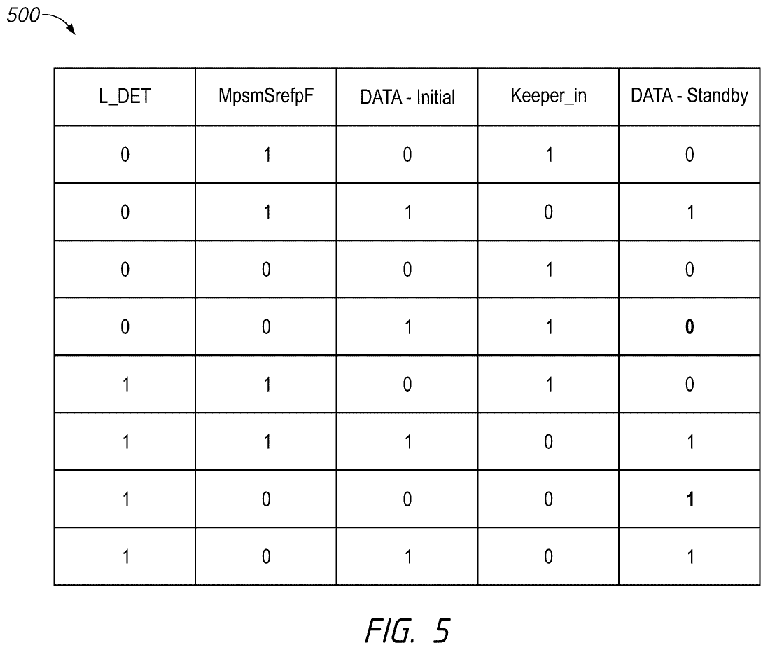

The combination logic circuit 412 may receive the leak detection signal L_DET and the keeper control signal MpsmSrefPF from the keeper control circuit 410. The combination logic circuit 412 also receives data having a logic state of the driver output at a node 422. The combination logic circuit 412 may provide a keeper internal signal keeper_in based on the leak detection signal L_DET, the keeper control signal MpsmSrefPF, and the data to the inverter 414. In some examples, the combination logic circuit 412 includes logic circuits that receive the L_DET and MpsmSrefPF signals, and data and provide the keeper_in signal to set a logic state to reduce leakage current of pull-up and/or pull-down transistors of driver circuits of the data path. In some embodiments, the logic circuit of the combination logic circuit 412 may operate according to a truth table, which will be described below with reference to FIG. 5. The combination logic circuit 412 may be implemented by the combination logic circuit 312 of FIG. 3 in some embodiments.

The inverter 414 is coupled to the combination logic circuit 412 and the signal line 456. The inverter 414 may set the standby logic state of the signal line 456 based on the keeper internal signal keeper_in. The standby logic state set for the signal line 456 may reduce current leakage. For example, the keeper internal signal keeper_in may cause the inverter 414 to switch logic states when the logic state of the initial data on the signal line 456 matches the logic state of the keeper internal signal keeper_in. As a result, the logic state of the standby data on the signal line 456 may be inverted. In another example, the inverter 414 is caused by the keeper internal signal keeper_in to maintain a logic state, for example, when the logic level of the standby data on the signal line may be the same as the logic level of the initial data. The inverter 414 may be implemented by the inverter 314 of FIG. 3.

In an example where the leakage current of the n-channel pull-down transistor is greater than the leakage current of the p-channel pull-up transistor, the leak detection circuit 418 provides the L_DET signal having a low logic state. As a result, the keeper internal signal keeper_in output from the combination logic 412 has a high logic state, and the inverter 414 sets the standby logic state of the driver output to a low logic state. In another example where the leakage current of the p-channel pull-up transistor is greater than the leakage current of the n-channel pull-down transistor, the leak detection circuit 418 provides the L_DET signal having a high logic state. As a result, the keeper internal signal keeper_in output from the combination logic 412 has a low logic state, and the inverter 414 sets the standby logic state of the driver output to a high logic state.

FIG. 5 is a truth table 500 in accordance with an embodiment of the present disclosure. The truth table 500 may be implemented by the combination logic circuit 312 of FIG. 3 and/or the combination logic circuit 412 of FIG. 4. The following discussion of the truth table 500 is based on an example implementation of the combination logic circuit 412.

As shown in FIG. 5, in a first example, the leak detection circuit 418 may provide a leak detection signal L_DET having a low logic state, indicating that the leakage current of the n-channel pull-down transistor is greater than the leakage current of the p-channel pull-up transistor. The pulse generator 420 may generate a MpsmSrefPF keeper control signal having a high logic state, indicating that the STANDBY signal is active during a self-refresh, Max Power Saving Mode (MPSM), and/or Pre-charge standby. The initial logic state of the data provided at a node 422 on the signal line 456 is “0”. Based on the L_DET signal, and the MpsmSrefPF keeper control signal, the combination logic 412 of the latch 416 generates a keeper internal signal keeper_in having a logic state of “1” to the inverter 414 of the latch 416. The inverter 414 may set the standby logic state of the driver output to be “0,” matching the initial logic state of the driver output.

In a second example, the leak detection circuit 418 may provide a leak detection signal L_DET having a low logic state, indicating that the leakage current of the n-channel pull-down transistor is greater than the leakage current of the p-channel pull-up transistor. The pulse generator 420 may generate a MpsmSrefPF keeper control signal having a high logic state, indicating that the STANDBY signal is active during a self-refresh, Max Power Saving Mode (MPSM), and/or Pre-charge standby. The initial logic state of the data provided at a node 422 on the signal line 456 is “1”. Based on the L_DET signal, and the MpsmSrefPF keeper control signal, the combination logic 412 of the latch 416 generates a keeper internal signal keeper_in having a logic state of “0” to the inverter 414 of the latch 416. The inverter 414 may set the standby logic state of the driver output to be “1,” matching the initial logic state of the driver output.

In a third example, the leak detection circuit 418 may provide a leak detection signal L_DET having a low logic state, indicating that the leakage current of the n-channel pull-down transistor is greater than the leakage current of the p-channel pull-up transistor. The pulse generator 420 may generate a MpsmSrefPF keeper control signal having a low logic state, indicating that the STANDBY signal is inactive. The initial logic state of the data provided at a node 422 on the signal line 456 is “0”. Based on the L_DET signal, and the MpsmSrefPF keeper control signal, the combination logic 412 of the latch 416 generates a keeper internal signal keeper_in having a logic state of “1” to the inverter 414 of the latch 416. The inverter 414 may set the standby logic state of the driver output to be “0,” matching the initial logic state of the driver output.

In a fourth example, the leak detection circuit 418 may provide a leak detection signal L_DET having a low logic state, indicating that the leakage current of the n-channel pull-down transistor is greater than the leakage current of the p-channel pull-up transistor. The pulse generator 420 may generate a MpsmSrefPF keeper control signal having a low logic state, indicating that the STANDBY signal is inactive. The initial logic state of the data provided at a node 422 on the signal line 456 is “1”. Based on the L_DET signal, and the MpsmSrefPF keeper control signal, the combination logic 412 of the latch 416 generates a keeper internal signal keeper_in having a logic state of “1” to the inverter 414 of the latch 416. The initial logic state for the driver output matches the logic state of the keeper internal signal keeper_in. The inverter 414 may set the standby logic state of the driver output to be “0.” Therefore, the logic state of the standby data on the driver output is inverted.

In a fifth example, the leak detection circuit 418 may provide a leak detection signal L_DET having a high logic state, indicating that the leakage current of the p-channel pull-down transistor is greater than the leakage current of the n-channel pull-up transistor. The pulse generator 420 may generate a MpsmSrefPF keeper control signal having a high logic state, indicating that the STANDBY signal is active during a self-refresh, Max Power Saving Mode (MPSM), and/or Pre-charge standby. The initial logic state of the data provided at a node 422 on the signal line 456 is “0”. Based on the L_DET signal, and the MpsmSrefPF keeper control signal, the combination logic 412 of the latch 416 generates a keeper internal signal keeper_in having a logic state of “1” to the inverter 414 of the latch 416. The inverter 414 may set the standby logic state of the driver output to be “0,” matching the initial logic state of the driver output.

In a sixth example, the leak detection circuit 418 may provide a leak detection signal L_DET having a high logic state. The pulse generator 420 may generate a MpsmSrefPF keeper control signal having a high logic state, indicating that the STANDBY signal is active during a self-refresh, Max Power Saving Mode (MPSM), and/or Pre-charge standby. The initial logic state of the data provided at a node 422 on the signal line 456 is “1”. Based on the L_DET signal, and the MpsmSrefPF keeper control signal, the combination logic 412 of the latch 416 generates a keeper internal signal keeper_in having a logic state of “0” to the inverter 414 of the latch 416. The inverter 414 may set the standby logic state of the driver output to be “1,” matching the initial logic state of the driver output.

In a seventh example, the leak detection circuit 418 may provide a leak detection signal L_DET having a high logic state. The pulse generator 420 may generate a MpsmSrefPF keeper control signal having a low logic state, indicating that the STANDBY signal is inactive. The initial logic state of the data provided at a node 422 on the signal line 456 is “0”. Based on the L_DET signal, and the MpsmSrefPF keeper control signal, the combination logic 412 of the latch 416 generates a keeper internal signal keeper_in having a logic state of “0” to the inverter 414 of the latch 416. The initial logic state for the driver output matches the logic state of the keeper internal signal keeper_in. The inverter 414 may set the standby logic state of the signal line 456 to be “1.” Therefore, the logic state of the standby data on the driver output is inverted.

In an eighth example, the leak detection circuit 418 may provide a leak detection signal L_DET having a high logic state. The pulse generator 420 may generate a MpsmSrefPF keeper control signal having a low logic state, indicating that the STANDBY signal is inactive. The initial logic state of the data provided at a node 422 on the signal line 456 is “1”. Based on the L_DET signal, and the MpsmSrefPF keeper control signal, the combination logic 412 of the latch 416 generates a keeper internal signal keeper_in having a logic state of “0” to the inverter 414 of the latch 416. The inverter 414 may set the standby logic state of the driver output to be “1,” matching the initial logic state of the signal line 456.

As seen in the above examples, the keeper control circuit 410 and the latch 416 may reduce leakage current of the pull-up and/or pull-down transistors of driver circuits of the data path.

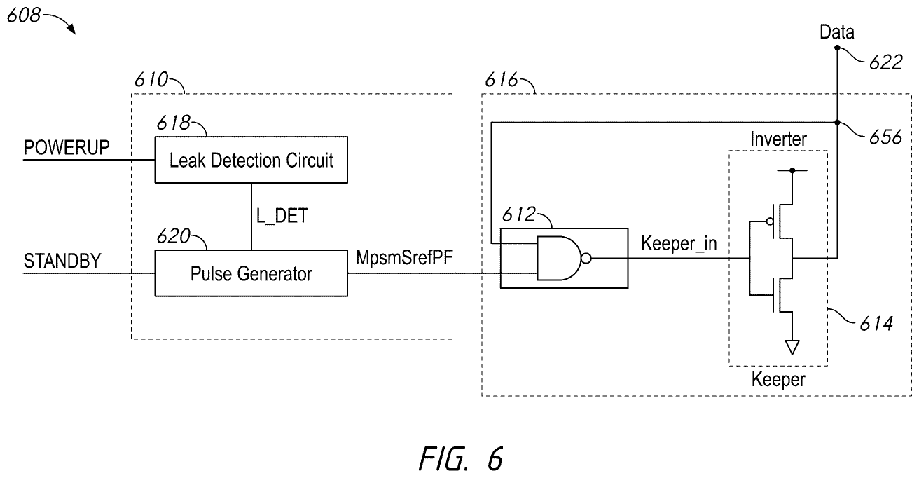

FIG. 6 is a schematic diagram of a keeper circuit 608 according to another embodiment of the present disclosure. The keeper circuit 608 includes a keeper control circuit 610 and a latch 616. The keeper circuit 608 may be included in the keeper circuit 208 of FIG. 2 in some embodiments. The keeper circuit 608 may be included in the keeper circuit 608 of FIG. 3. The latch 616 may be included in the latch 316 of FIG. 3. The keeper circuit 608 shows a modification to the keeper circuit 408 shown in FIG. 4.

The keeper control circuit 610 includes a leak detection circuit 618 and a pulse generator 620. The keeper control circuit 610 may determine a leakage characteristic of a driver of a data path (e.g., driver circuit 206a/206b of FIG. 2 and/or driver circuit 324/330 of FIG. 3) and provide a leak detection signal L_DET according to the leakage characteristic. The leakage characteristic may be based on a comparison of the p-channel leakage and the n-channel leakage of a replica driver circuit (described with reference to replica circuit 806 of FIG. 8 below). The replica driver circuit may include pull-up and pull-down transistors that have transistor characteristics that model the transistor characteristics of pull-up and pull-down transistors included in the driver circuits of a data path.

For example, the leak detection circuit 618 may determine the if the n-channel pull-down transistor leakage is greater than the p-channel pull-up transistor leakage during power up. For example, if the n-channel pull-down transistor leakage is greater than the p-channel pull-up transistor leakage, the leak detection signal L_DET may be set to high; if the p-channel pull-up transistor leakage is greater than the n-channel pull-down transistor leakage, the leak detection signal L_DET may be set to low. The leak detection signal L_DET may be provided to a pulse generator 620 in the keeper control circuit 610.

The pulse generator 620 may generate a keeper control signal MpsmSrefPF based on the logic state of control signal STANDBY and the leak detection signal L_DET. The STANDBY signal is active when a semiconductor device including the keeper circuit 608 is in standby. The STANDBY signal may be provided by a command decoder (e.g., command decoder 115 of FIG. 1) in some embodiments. In some examples, the STANDBY control signal may be active during a self-refresh, Max Power Saving Mode (MPSM), and/or Pre-charge standby. The pulse generator 620 provides a pulse for the MpsmSrefPF control signal when the STANDBY control signal becomes active and when the leak detection signal L_DET is set to high to set the logic state of the latch 616, which in turn sets a standby logic state of the signal line 656 (e.g., low). In some examples, when the leak detection signal L_DET is low, the p-channel pull-up transistor has a greater leakage than the n-channel pull-down transistor and the signal line 656 is not set by the keeper control circuit 610. The signal line 656 may be implemented by the signal line 156 of FIG. 1, the signal line 256 of FIG. 2, and/or the signal line 356 of FIG. 3.

The latch 616 receives the keeper control signal MpsmSrefPF from the keeper control circuit 610. As shown in FIG. 6, the latch 616 includes a NAND gate 612 and an inverter 614. The latch 616 is coupled to the signal line 656. In some examples, the latch 616 may have a logic state, which is set by the keeper control signal MpsmSrefPF. The logic state of the latch 616 sets the standby logic state of the signal line 656.

The NAND gate 612 receives the keeper control signal MpsmSrefPF from the keeper control circuit 610 and data having a logic state from the driver output at a node 622. The NAND gate 612 may provide a keeper internal signal keeper_in based on the keeper control signal MpsmSrefPF and the data to the inverter 614. In some examples, the NAND gate 612 may provide the keeper_in signal to set a logic state to reduce leakage current of pull-up and/or pull-down transistors of driver circuits of the data path. In some embodiments, the NAND gate 612 may be implemented by the combination logic circuit 312 of FIG. 3 in some embodiments.

The inverter 614 is coupled to the NAND gate 612 and the driver output. The inverter 614 may set the standby logic state of the driver output based on the keeper internal signal keeper_in. The standby logic state set for the driver output may reduce current leakage. For example, the keeper internal signal keeper_in may cause the inverter 614 to switch logic states when the logic state of the initial data on the signal line 656 matches the logic state of the keeper internal signal keeper_in. As a result, the logic state of the standby data on driver output may be inverted. In another example, the inverter 614 is caused by the keeper internal signal keeper_in to maintain a logic state, for example, when the logic state of the standby data on the driver output may be the same as the logic state of the initial data. The inverter 614 may be implemented by the inverter 314 of FIG. 3.

In an example where the leakage current of the n-channel pull-down transistor is greater than the leakage current of the p-channel pull-up transistor, the leak detection circuit 618 provides the L_DET signal having a low logic state. As a result, the keeper internal signal keeper_in output from the NAND gate 612 has a high logic state, and the inverter 614 sets the standby logic state of the driver output to a low logic state. In another example where the leakage current of the p-channel pull-up transistor is greater than the leakage current of the n-channel pull-down transistor, the leak detection circuit 618 provides the L_DET signal having a high logic state. As a result, the keeper internal signal keeper_in output from the NAND gate 612 has a low logic state, and the inverter 614 sets the standby logic state of the driver output to a high logic state.

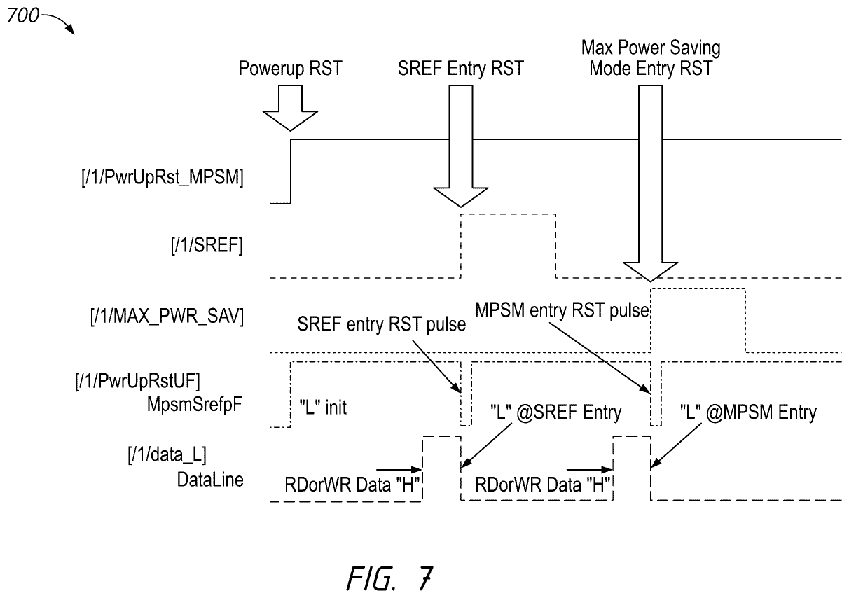

FIG. 7 is an example timing diagram 700 according to an embodiment of the present disclosure (e.g., the operation of the keeper circuit 608 of FIG. 6).

In some examples, the MpsmSrefPF keeper control signal output by the keeper control circuit 610 may be set at “1” at power up as indicated by the activation of PwrUpRst_MPSM; and the MpsmSrefPF keeper control signal may be set at “0” at self-refresh as indicated by the activation of SREF and/or max power saving mode as indicated by the activation of MAX_PWR_SAV. The MpsmSrefPF keeper control signal that was at “0” may be set at “1” following a pulse.

The data line data_L may indicate read or write data (RDorWR Data) in a read or write operation. In some examples, the logic state of the data line data_L changes from “1” to “0” at the activation of SREF and/or the activation of Max Power Saving Mode, as indicated by the logic state of the MpsmSrefPF keeper control signal.

FIG. 8 is a schematic diagram of a leak detection circuit 800 according to an embodiment of the present disclosure. The leak detection circuit 800 includes a Vref circuit 802, a leak detection control logic 804, a replica circuit of a data driver 806, and a comparator 808. The leak detection circuit 800 may be included in the leak detection circuit 418 of FIG. 4 and/or the leak detection circuit 618 of FIG. 6.

The Vref circuit 802 generates a reference voltage Vref having a voltage level between the supply voltage VSS and the ground voltage GND. In some examples, the reference voltage Vref may be half the supply voltage VSS. As shown in FIG. 8, the reference voltage may be provided to a comparator 808.

The leak detection control logic 804 is configured to receive a control signal POWERUP (e.g., during power-up) and is coupled to the replica circuit 806. The leak detection control logic 804 may enable the replica circuit 806 to provide a leak voltage V_LEAK based on a leakage of the inactive p-channel pull-up transistor and the inactive n-channel pull-down transistor of the driver.

The replica circuit 806 may have the structure of a data driver (e.g., drivers 206a and 206b of FIG. 2 and/or driver circuit 324/330 306 of FIG. 3). The replica circuit 806 includes a p-channel pull-up transistor and an n-channel pull-down transistor. The replica circuit 806 may provide a leak voltage V_LEAK based on a leakage of the p-channel pull-up transistor or the n-channel pull-down transistor of the driver. The control signal V_LEAK may be compared with the reference voltage VREF at a comparator 808.

The comparator 808 may compare the reference voltage VREF provided by the VREF circuit 802 and the leak voltage V_LEAK provided by the replica circuit 806. The comparator 808 may provide a leak detection signal L_DET according to the leakage characteristic of the replica circuit 806 based on the comparison.

For example, the leak detection circuit 800 may provide a leak detection signal L_DET set at high if the p-channel pull-up transistor leakage is greater than the n-channel pull-down transistor leakage; or provide a leak detection signal L_DET set at low if the n-channel pull-down transistor leakage is greater than the p-channel pull-up transistor leakage.

In some embodiments, the leak detection circuit 800 includes an inverter to provide an L_DET signal that has opposite logic states than previously described. For example, in some embodiments of the disclosure the leak detection circuit 800 may provide a leak detection signal L_DET set at low if the p-channel pull-up transistor leakage is greater than the n-channel pull-down transistor leakage; or provide a leak detection signal L_DET set at high if the n-channel pull-down transistor leakage is greater than the p-channel pull-up transistor leakage. The leak detection signal L_DET may be provided to a pulse generator 620 in the keeper control circuit 610.

Certain details are set forth above to provide a sufficient understanding of described embodiments. However, it will be clear to one skilled in the art that embodiments may be practiced without various of these particular details. The description herein, in connection with the appended drawings, describes example configurations and does not represent all the examples that may be implemented or that are within the scope of the claims. The terms “exemplary” and “example” as may be used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Other examples and implementations are within the scope of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations.

Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

From the foregoing it will be appreciated that, although specific embodiments have been described herein for purposes of illustration, various modifications may be made while remaining with the scope of the claimed technology. The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. An apparatus comprising:
a data path comprising:
a signal line;
a repeater circuit including:
a receiver configured to receive data along the data path, the data having a logic state; and
a driver configured to transmit the data along the data path; and
a keeper circuit coupled to a node at an output of the driver and configured to set a standby logic state of the node, the keeper circuit including:
a keeper control circuit configured to determine a leakage characteristic of the driver and provide a leak detection signal and a keeper control signal based on the leakage characteristic; and
a latch coupled to the signal line, the latch configured to have a latch logic state based on the keeper control signal and further configured to set the standby logic state of the output of the driver based on the latch logic state.

2. The apparatus of claim 1, wherein the keeper control circuit comprises:
a leak detection circuit configured to determine the leakage characteristic and generate the leak detection signal during a power up sequence; and
a pulse generator configured to generate the keeper control signal during standby.

3. The apparatus of claim 2, wherein the leak detection circuit is configured to determine the leakage characteristic by comparing leakage currents between transistors of the driver.

4. The apparatus of claim 2, wherein the leak detection circuit is configured to provide the leak detection signal to the latch.

5. The apparatus of claim 2, wherein the leak detection circuit is configured to provide the leak detection signal to the pulse generator, and wherein the pulse generator is further configured to generate the keeper control signal based on the leak detection signal.

6. The apparatus of claim 2, wherein the leak detection circuit comprises:
a leak detection control logic;
a voltage reference circuit configured to provide a reference voltage; and
a comparator coupled to the leak detection control logic and the driver, wherein the driver is configured to provide a leak voltage of the driver, and wherein the comparator is configured to compare the voltage reference and the leak voltage to generate the leak detection signal.

7. The apparatus of claim 6, wherein the leak detection circuit further comprises a replica circuit comprising:
a p-channel transistor; and
an n-channel transistor.

8. The apparatus of claim 1, wherein the latch comprises:
a combination logic circuit configured to receive the keeper control signal and the logic state of the data and provide a keeper internal signal based on the leak detection signal, the keeper control signal and the logic state of the data; and
an inverter coupled to the combination logic circuit and coupled to the signal line, the inverter configured to set the standby logic state based on the keeper internal signal.

9. The apparatus of claim 1, wherein the driver is a tri-state driver.

10. A method comprising:
determining a leakage characteristic of a driver having a driver output coupled to a signal line;
providing a leak detection signal and a keeper control signal to a latch based on the leakage characteristic;
setting a latch logic state of the latch based on the keeper control signal; and
setting a standby logic state of the driver output based on the latch logic state.

11. The method of claim 10, further comprising:
generating the leak detection signal during a power up sequence; and
generating the keeper control signal during standby.

12. The method of claim 11, further comprising: comparing leakage currents between transistors of the driver to determine the leakage characteristic.

13. The method of claim 11, further comprising:
comparing a voltage reference and a leak voltage of the driver to generate the leak detection signal.

14. The method of claim 10, further comprising:
providing a keeper internal signal based on the keeper control signal and a logic state of data on the driver output; and
setting the standby logic state based on the keeper internal signal.

15. The method of claim 10, wherein the driver is a tri-state driver.

16. An apparatus comprising:
a tri-state data driver configured to transmit data along a data path and coupled to a signal line; and
a keeper circuit coupled to a node at an output of the tri-state data driver, the keeper circuit comprises:
a keeper control circuit configured to determine a leakage characteristic of the tri-state data driver based on leakages of transistors of the tri-state data driver; and
a latch configured to set a standby logic state of the output of the tri-state driver based on the leakage characteristic.

17. The apparatus of claim 16, wherein the keeper control circuit comprises:
a leak detection circuit configured to generate a leak detection signal indicative of a first transistor of the tri-state data driver has greater leakage than a second transistor of the tri-state data driver;
a pulse generator configured to generate a keeper control signal based on a standby control signal, wherein the keeper control signal provided to the latch to set the standby logic state of the output of the tri-state driver.

18. The apparatus of claim 17, wherein the pulse generator is further configured to generate the keeper control signal based on the leak detection signal from the leak detection circuit, wherein the latch further comprises a logic gate, and wherein the keeper control signal and the logic state of the data are provided to the logic gate to set the standby logic state of the output of the tri-state driver.

19. The apparatus of claim 17, wherein the latch further comprises:
a combination logic circuit configured to receive the keeper control signal and the logic state of the data and provide a keeper internal signal based on the leak detection signal, the keeper control signal, and the logic state of the data; and
an inverter coupled to the combination logic circuit and coupled to the output of the tri-state driver, the inverter configured to set the standby logic state based on the keeper internal signal.

20. The apparatus of claim 19, wherein the inverter is configured to set the standby logic state of the output of the tri-state driver to be different from the logic state of the data when the keeper internal signal and the data have a same logic state.
